(19) United States
(12) Patent Application Publication
(10) Pub. No.: US 2015/0204948 A1
(43) Pub. Date: Jul. 23, 2015

(54) METHOD OF PRODUCING AN ELECTRIC BATTERY

(71) Applicant: COMMISSARIAT A L'ENERGIE ATOMIQUE ET AUX ENERGIES ALTERNATIVES, PARIS (FR)

(72) Inventors: Fathia Karoui, Villeubranne (FR); Elisabeth Lemaire, Les Abrets (FR); Nicolas Martin, Albertville (FR)

(21) Appl. No.: 14/419,412

(22) PCT Filed: Aug. 6, 2013
(86) PCT No.: PCT/FR2013/051898

§ 371 Date: Feb. 3, 2015

(30) Foreign Application Priority Data
Aug. 8, 2012 (FR) 1257690

(51) Int. Cl. G01R 31/36; H01M 10/48; H01M 6/42; H01M 10/42

(52) U.S. Cl. CPC G01R 31/3658; H01M 10/4207; H01M 10/482; H01M 6/42; H01M 10/633; G01R 31/3662; G01R 31/3648

(57) ABSTRACT

The invention relates to a method of producing a battery (14), in which method multiple cells (c1-c12) are arranged in receiving locations, taking account of the respective internal resistances of the cells and the suitability of each individual location to dissipate heat. For example, the most resistive cells can be assigned the locations best suited to dissipating heat. In this way, the invention can be used to produce a battery in which the temperature rise is reduced, such that battery life is improved.

### CROSS-REFERENCE TO RELATED APPLICATIONS

The present application is a National Stage of PCT International Application Serial Number PCT/FR2013/051898, filed Aug. 6, 2013, which claims priority under 35 U.S.C. §119 of French Patent Application Serial Number 12/57690, filed Aug. 8, 2012, the disclosures of which are incorporated by reference herein.

### BACKGROUND OF THE INVENTION

1. Field of the Invention

The present invention generally relates to electric batteries, and more particularly aims at a battery manufacturing method.

2. Description of the Related Art

In certain batteries, some cells may, in operation, undergo a significant heating, which raises premature aging issues, which may result in a loss of charge holding capacity of the battery and a decrease of its lifetime. This further generates a significant need for balancing.

Patent application JP2004303456 describes a solution which has been provided to attempt to increase the lifetime of a battery. In this document, it is provided to place, at the locations of the battery where the heat removal is the poorer, cells having an internal resistance lower by at least 15% than the other cells.

Patent application JP2008084691 describes a solution which has been provided to attempt to decrease degradations due to the repeating of the charge/remove cycles in a battery. In this document, the cells are identical to within manufacturing dispersions. It is provided to measure the internal resistance of each cell before assembly, and then to perform the assembly by arranging the cells so that each cell is surrounded with two cells of stronger or lower internal resistance (that is, by alternating cells of strong/low internal resistance).

### SUMMARY

An object of an embodiment of the present invention is to form a battery overcoming all or part of the disadvantages of existing batteries.

An object of an embodiment of the present invention is to form a battery where the heating of the elementary cells is lower than in existing batteries.

Another object of an embodiment of the present invention is to form a battery having a lifetime improved with respect to existing batteries.

Thus, an embodiment of the present invention provides a method of forming a battery, wherein a plurality of cells are arranged, taking into account their respective internal resistances.

According to an embodiment of the present invention, a location in the battery is assigned to each cell, taking into account the respective heat removal abilities of the locations.

According to an embodiment of the present invention, the method comprises a step of measuring the internal resistance of each cell.

According to an embodiment of the present invention, the locations having the highest heat removal abilities are assigned to the most resistive cells, and conversely.

According to an embodiment of the present invention, the locations having the highest heat removal abilities are assigned to the cells dissipating the largest quantity of energy by Joule effect, and conversely.

According to an embodiment of the present invention, the layout takes into account the diagram of electric connection of the cells of the battery.

According to an embodiment of the present invention, the elementary cells are identical except for manufacturing dispersion.

Another embodiment of the present invention provides an electric battery comprising a plurality of elementary cells formed by the above-mentioned method.

According to an embodiment of the present invention, the elementary cells comprise lithium.

According to an embodiment of the present invention, the elementary cells are series-connected.

### BRIEF DESCRIPTION OF THE DRAWINGS

The foregoing and other features and advantages will be discussed in detail in the following non-limiting description of specific embodiments in connection with the accompanying drawings, among which:

FIG. 1 is a perspective view schematically showing an embodiment of an electric battery;

FIG. 2 is a block diagram illustrating steps of an embodiment of an electric battery manufacturing method;

FIG. 3 is a block diagram illustrating steps of another embodiment of an electric battery manufacturing method; and

FIG. 4 is a block diagram illustrating steps of an alternative embodiment of an electric battery manufacturing method.

### DETAILED DESCRIPTION

An electric battery is a group of a plurality of elementary cells (cells, accumulators, etc.) connected in series and/or in parallel between two nodes or terminals for providing a D.C. voltage.

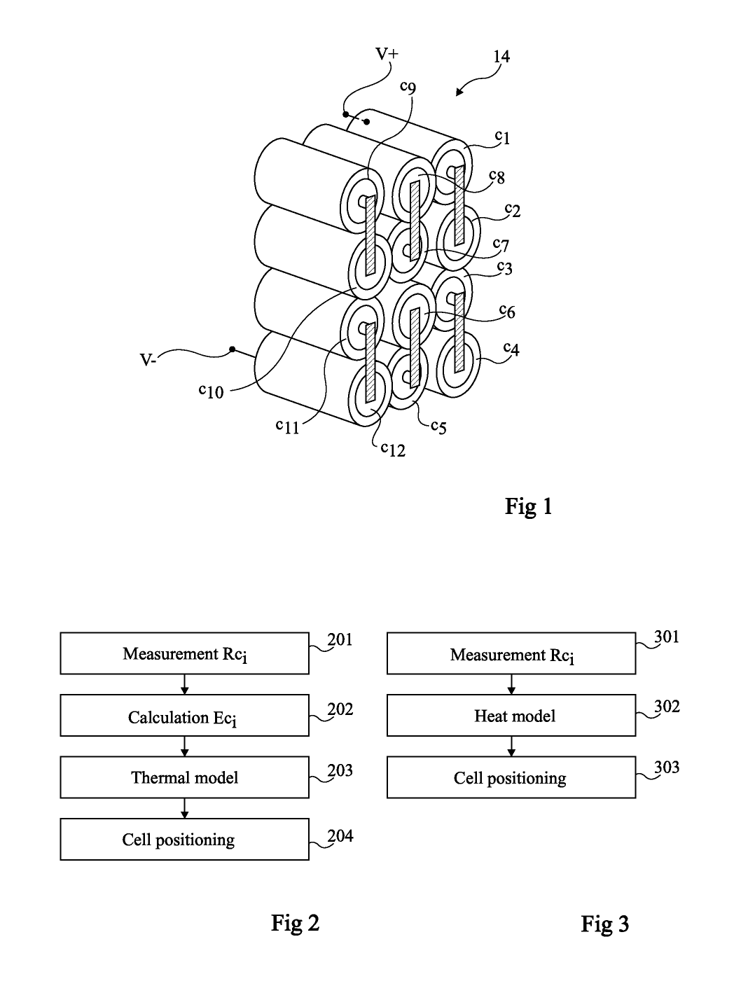

FIG. 1 is a perspective view schematically showing an embodiment of a battery 14 comprising twelve elementary cells ci, i being an integer in the range from 1 to 12, series-connected between terminals V+ and V− for delivering a D.C. voltage. The battery cells are generally housed in a protection package (not shown) only leaving access to two lugs respectively connected to terminals V+ and V− of the battery.

The locations for receiving the cells in the battery and their respective positioning relative to one another are defined according to the constraints of the system using the battery, to the shape of the packaging, to the number of cells to be placed in the battery, etc.

In the absence of a specific cooling system, the locations of the cells within a battery generally do not have the same heat removal ability (or cooling capacity). As an example, in battery 14 of FIG. 1, the heat generated by peripheral cells c1 to c5 and c8 to c12, having a relatively large surface area of exchange with the outside, is more easily removed than the heat generated by central cells c6 and c7, which are more confined. As a result, certain cells heat more than others, and thus age faster.

The premature aging of certain battery cells under the effect of heat significantly impacts the performance of the battery as a whole, even if such cells are few with respect to the total number of battery cells. Indeed, the aging of an elementary cell translates as a decrease of its capacity and/or an increase of its resistance. Now, batteries are generally provided with management systems configured to interrupt the battery charge or remove as soon as the charge or the remove of the elementary cells of smaller capacity is over. The battery performance is thus limited by that of its elementary cells of lowest capacity.

To limit the cell heating, batteries where the cells are spaced apart from one another and a cooling fluid flows through the free spaces between cells may be provided. Batteries where metal parts are arranged between cells to facilitate the heat removal may also be provided. Such systems are however expensive and increase the weight and the bulk of the battery.

Independently from differences in thermal behavior between the different locations, in practice, the elementary cells of a battery, although theoretically identical, are subject to manufacturing dispersions. The inventors have particularly observed that the elementary cells of a battery do not all have exactly the same internal resistance, including when they are new. As a result, in operation, under the effect of the currents flowing in the battery, some cells heat up more than others, and thus age more rapidly.

According to an aspect, it is provided, before assembling the battery, to measure the internal resistance of each of the cells, and to select the location of each cell in the volume where the cells of the formed battery are contained, while taking into account its internal resistance and the thermal behavior of the locations, to optimize the battery performance. The internal resistances of the different cells are preferably measured in identical conditions. As an example, the measurements are performed for fully charged cells, for a substantially zero internal current, and at a temperature in the order of 25° C. The described embodiments are of course not limited to this specific case.

FIG. 2 is a block diagram illustrating steps of an embodiment of an electric battery manufacturing method.

At a step 201 (measurement Rci), internal resistance Rci of each of the elementary cells of the battery is measured.

At a step 202 (calculation Eci), taking into account the architecture (or electric diagram) of the battery, and particularly the current distribution in the battery in operation, as well as the internal resistances Rci measured at step 201, the elementary cells are classified according to the amount of energy Eci that they are capable of dissipating by Joule effect during the battery operation.

As an example, when the elementary cells are series-connected, they all conduct a same current I, equal to the total current flowing between terminals V+ and V− of the battery. The quantity of energy dissipated (or quantity of heat generated) by each elementary cell is proportional to the product of its internal resistance Rci by the square of current I flowing therethrough. The cells having the highest internal resistances Rci are thus those which generate the most heat, and conversely.

When the elementary cells are connected in parallel, current I crossing the battery divides into as many elementary currents Ici as the battery comprises cells. In each elementary cell, current Ici is all the higher as internal resistance Rci of the cell is low, and conversely. The sum of currents Ici is equal to total current I flowing between terminals V+ and V− of the battery. The quantity of heat generated by a cell is proportional to the product of its internal resistance Rci by the square of current Ici flowing therethrough. The inventors have observed that in practice, at the scale of manufacturing dispersions, more energy is dissipated in lightly-resistive cells than in strongly-resistive cells. The cells having the lowest internal resistances (high currents Ici) are thus those which generate the most heat, and conversely.

At a step 203 (thermal model), a thermal model of the battery is determined. During this step, for each location, one or a plurality of parameters representative of the ability of the location to remove heat, or cooling capacity of the location, may be determined. The locations of the battery cells are classified according to their ability to remove heat, or cooling capacity. As an example, each location may be arbitrarily assigned a cooling capacity inversely proportional to the distance which separates it from the battery protection package. As a variation, a more elaborate thermal model may be determined by calculation and simulation of heat exchanges within the battery during its operation.

At a step 204 (placing of the cells), a location is assigned to each elementary cell, by taking into account the quantity of heat generated by the cell in operation (linked to its internal resistance) and the cooling capacity of the location, to minimize temperature differences within the battery during its operation. In other words, the locations having a high ability to remove heat are assigned to cells generating a large quantity of heat, and conversely.

As an example of a simple method of assignment of the locations to the cells, if a classification of the cells by increasing order of quantity of generated heat is performed at step 202, and if a classification of the locations by increasing order of cooling capacity is performed at step 203, the first location of the location classification is assigned to the first cell of the cell classification, the second location of the location classification is assigned to the second cell of the cell classification, and so on. It should however be noted that in this example, the method of assigning locations to cells does not take into account the fact that the quantity of heat generated by a cell actually depends on the temperature of this cell, which itself depends on the cell location. Indeed, the internal resistance of a cell is generally all the higher as the cell temperature is low.

As a variation, more sophisticated methods of assigning locations to cells may be provided. The assignment method may further comprise one or a plurality of optimization algorithms in which a selected criterion or parameter is maximized or minimized. The optimization algorithms may have a plurality of iterations.

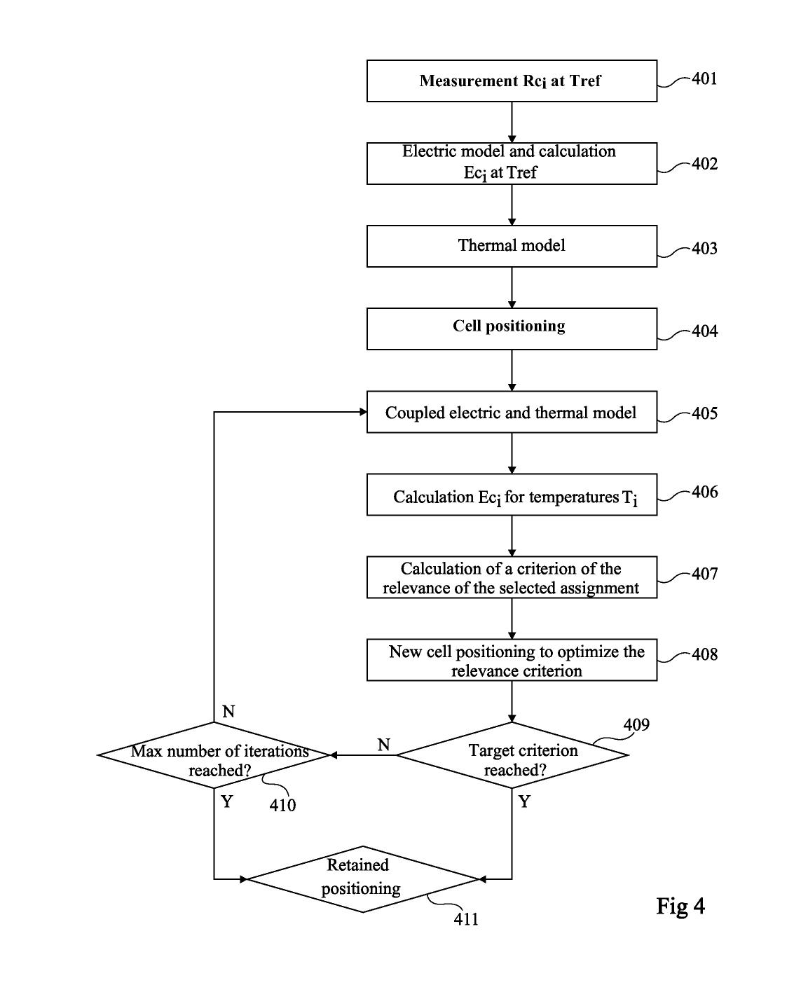

FIG. 4 is a block diagram illustrating an embodiment of such an improved method of assigning locations to the cells.

During a step 401 (measurement Rci at Tref), internal resistance Rci of each of the elementary cells of the battery is measured at a reference temperature Tref identical for all the battery cells.

At a step 402 (electric model and calculation Eci at Tref), taking into account the architecture (or electric diagram) of the battery, and particularly the current distribution in the battery in operation, as well as the internal resistances Rci measured at step 401, the elementary cells are classified according to the quantity of energy Eci that they are capable of dissipating by Joule effect during the operation of the battery at temperature Tref.

At a step 403 (thermal model), a thermal model of the battery is determined During this step, for each location, one or a plurality of parameters representative of the ability of the location to remove heat, or cooling capacity of the location, may be determined The battery cell locations may be classified according to their ability to remove heat, or cooling capacity.

At a step 404 (placing of the cells), a location is assigned to each elementary cell, taking into account the quantity of heat generated by the cell in operation at temperature Tref (determined at step 402) and the cooling capacity of the location (determined at step 403). During this step, a simple assignment method of the above-mentioned type (assignment of the locations having a good ability to remove heat to cells generating a large quantity of heat, and conversely) may for example be used.

In the example of FIG. 4, steps 401, 402, 403, and 404 define an initialization phase of the method.

At a step 405 (coupled electric and thermal model), it is provided to estimate, for each cell and for the initial assignment performed at steps 401, 402, 403, and 404 (particularly taking into account the capacity of the location assigned to each cell to remove heat, and the quantity of energy capable of being dissipated by each cell at temperature Tref), the effective operating temperature Ti of the cell.

At a step 406 (calculation Eci for temperatures Ti), it is provided, for each cell, to estimate the effective internal resistance of the cell at its effective operating temperature Ti. Based on this effective internal resistance, it is provided to calculate the quantity of energy Eci effectively dissipated by Joule effect by each cell in operation. During step 405, operating temperatures Ti of the different cells may be different from one another and different from reference temperature Tref. The internal resistances of the cells determined at step (106 may thus be different from those measured at step 401. To estimate internal resistance Rci(Ti) of a cell at a temperature Ti other than temperature Tref used on measurement of the internal resistance (step 401), a function enabling to calculate Rci(Ti) according to Rci(Tref), Tref, and Ti, where Rci(Tref) is the internal resistance of the cell measured at temperature Tref, may be used.

At a step 407 (calculation of a criterion of relevance of the selected assignment), it is provided to calculate a criterion enabling to assess the relevance of the assignment of the locations to the cells, for example, the maximum temperature difference between the different cells of the battery, the total electric power consumption of the battery, etc.

At a step 408 (new positioning of the cells to optimize the relevance criterion), it is provided to define a new assignment of the locations to the cells, while trying to improve—decrease or increase—the selected relevance criterion.

At a test step 409 (target criterion reached?), it is verified whether the selected relevance criterion has reached a target value. If it has (Y), the current positioning of the cells is retained as the final positioning to form the battery at a step 411 (retained positioning). If it has not (N), it is verified, during a test step 410 (max number of iterations reached?), whether a maximum number of iterations of the iterative portion of the method has been reached. If the maximum number of iterations has been reached (Y), the current positioning of the cells is retained as the final positioning to form the battery. If the maximum number of iterations has not been reached (N), it is provided to repeat above-mentioned steps 405 to 411, and so on until the target value of the relevance criterion or the maximum authorized number of iterations is reached. The most favorable assignment regarding the selected relevance criterion is then retained for the final positioning of the cells.

In subsequent steps, not shown, the elementary cells are assembled and connected to one another to form the battery.

An advantage of the embodiment of FIG. 2 and of the alternative embodiment of FIG. 4 is that by placing the cells having the greatest propensity to generate heat at the locations most capable of removing heat, the temperature rise of these cells, and accordingly their aging, is limited. The battery lifetime is thus extended and the variation of its performance along time is improved.

FIG. 3 is a block diagram illustrating steps of another embodiment of an electric battery manufacturing method.

At a step 301 (measurement Rci), internal resistance Rci of each of the elementary cells of the battery is measured.

At a step 302 (thermal model), for example, identical to step 203 of the method of FIG. 2, a thermal model of the battery is determined, that is, the cell locations in the battery are classified according to their ability to remove heat, or cooling capacity.

At a step 303 (cell positioning), a location is assigned to each elementary cell of the battery, taking into account internal resistance Rci of the cell and the cooling capacity of the location, so that the locations having a high ability to remove heat are assigned to cells of strong resistivity, and conversely.

As an example of a simple method of assignment of the locations to the cells, if a classification of the cells by increasing order of resistivity is performed at step 301, and if a classification of the locations by increasing order of cooling capacity is performed at step 302, the first location of the location classification Is assigned to the first cell of the cell classification, the second location of the location classification is assigned to the second cell of the cell classification, and so on. More sophisticated assignment methods, for example, of the type described in relation with FIG. 4, comprising optimizing a relevance criterion of the assignment, may however be provided.

The elementary cells are then attached and connected to one another to form the battery.

An advantage of the embodiment of FIG. 3 is that it enables to homogenize, over time, the internal resistances of the different cells, which may enable to decrease the effort made to balance the different battery cells during the battery lifetime. Indeed, the aging of a cell under the effect of heat translates as an increase of the internal resistance of this cell. Thus, during a given time period, a cell submitted to a significant heating will see its internal resistance increase more strongly than a cell submitted to a lower heating, and conversely. The embodiment of FIG. 3 thus uses the disparity of ability of the locations to remove heat, so that the cell aging brings about a compensation of the manufacturing dispersion of cells.

It should be noted that in the case of a series connection of the cells, the embodiments of FIGS. 2 and 3 correspond to a same layout of the cells in the battery, that is, the less confined locations are assigned to the most resistive cells, and conversely. The advantages of the two embodiments are then cumulated. However, in the case of a parallel assembly of the cells, the embodiments of FIGS. 2 and 3 correspond to different layouts: in the embodiment of FIG. 2, the least confined locations are assigned to the least resistive cells and conversely, whereas in the embodiment of FIG. 3, the least confined locations are assigned to the most resistive cells, and conversely. One embodiment rather than the other may be preferred according to the conditions of the use of the battery. For example, if the battery is intended to operate in a well-cooled environment where critical temperature thresholds will never be reached, even in the most confined cells, the embodiment of FIG. 3 may be preferred.

An advantage of the embodiments described in relation with FIGS. 2 and 3 is that they are easy to implement and to not increase the battery weight. This is particularly advantageous in the case of a use of the battery for an embarked application, for example, in an electric bicycle.

Further, the described embodiments are particularly advantageous for batteries using lithium cells or nickel-metal hydride (NiMH) cells, which are particularly heat-sensitive.

Further, the described embodiments are particularly advantageous for high-power batteries such as batteries for an electric vehicle or storage batteries connected to an electric network (for example, storage batteries for frequency regulation, for example, in solar power plants), where temperature rises may be particularly significant.

It should be noted that in the described embodiments, the steps between the measurement of the internal resistances Rci of the different cells and the actual assembly of the battery may be carried out by means of a calculation unit such as a computer. As an example, the values of the internal resistances of the different cells may be communicated to the computer, which, knowing the thermal model of the battery or being capable of determining it, and possibly knowing the electric diagram of the battery, automatically assigns a location in the battery to each elementary cell, for example, according to a simple assignment algorithm of the above-mentioned type, or according to a more sophisticated algorithm of the type described in FIG. 4, comprising an iterative method of optimization of a criterion of qualification of the assignment of locations to the cells.

Specific embodiments of the present invention have been described. Various alterations, modifications, and improvements will readily occur to those skilled in the art.

In particular, a battery is known to be dividable into a plurality of modules, each comprising a plurality of cells connected in series or in parallel between two contact nodes or terminals of the module, the modules being connected in series or in parallel between the battery terminals. Although this has not been mentioned hereabove, it will be within the abilities of those skilled in the art to add modularity to the above-described embodiments.

Further, the invention is not limited to batteries using lithium cells or NiMH cells. It will be within the abilities of those skilled in the art to implement the above-mentioned methods to form batteries using other types of elementary cells.

Further, in the above-described examples, the battery is not equipped with a complementary cooling or heat removal system. The described embodiments are however not limited to this specific case. It will be within the abilities of those skilled in the art to form a battery where the positioning of the elementary cells takes into account their internal resistances, this battery further comprising complementary cooling or heat removal means. In this case, an advantage of the provided embodiments is that the complementary cooling system may be undersized with respect to cooling systems provided in existing batteries or, if it is not undersized, that the cell temperature during the battery operation is decreased as compared with existing batteries, which extends the battery lifetime.

Finally, the practical implementation of the embodiments which have been described is within the abilities of those skilled in the art based on the functional indications described hereabove.

1. A method of forming a battery comprising a plurality of cells, comprising the steps of:
defining locations for receiving the cells and the relative positionings of these locations in the battery;
measuring the internal resistance of each cell;
determining, for each location, a parameter representative of the heat removal ability of the location; and
assigning a location in the battery to each cell, taking into account respective internal resistances of the cells and the respective heat removal abilities of the locations.

2. The method of claim 1, wherein the plurality of cells are identical except for manufacturing dispersion.

3. The method of claim 1, wherein the locations having the highest heat removal abilities are assigned to the most resistive cells.

4. The method of claim 1, wherein the locations having the highest heat removal abilities are assigned to the cells dissipating the largest quantity of energy by Joule effect.

5. The method of claim 4, wherein the assignment of the locations to the cells comprises the following step sequence:
classifying the locations by order of heat removal ability;
classifying the cells by order of quantity of heat dissipated by Joule effect at a reference temperature; and
assigning the locations having the highest heat removal abilities to the cells dissipating the largest quantity of energy at said reference temperature.

6. The method of claim 1, wherein the assignment of the locations to the cells comprises an initial assignment of the locations to the cells, and then further comprises one or a plurality of iterations of the following step sequence:
a) calculating, for each cell, the quantity of energy dissipated by Joule effect by the cell in operation, taking into account the heat removal capacity of the location assigned to the cell during a previous sequence;
b) calculating a criterion characteristic of the relevance of the assignment of the locations to the cells; and
c) defining a new assignment of the locations to the cells.

7. The method of claim 6, wherein a plurality of iterations of said sequence are implemented, and wherein, at the end of said iterations, the most favorable assignment relative to said criterion is retained.

8. The method of claim 6, wherein said criterion is the maximum temperature difference between the different cells of the battery in operation.

9. The method of claim 6, wherein said criterion is the total electric power consumption of the battery.

10. The method of claim 1, wherein said layout takes into account the diagram of electric connection of the cells of the battery.

11. The method of claim 1, wherein the assignment of the locations to the cells is determined by means of a calculation unit.

12. An electric battery comprising a plurality of elementary cells, the plurality of elementary cells being positioned within the battery by the method comprising the steps of:
defining locations for receiving the cells and the relative positionings of these locations in the battery;
measuring the internal resistance of each cell;
determining, for each location, a parameter representative of the heat removal ability of the location; and
assigning a location in the battery to each cell, taking into account respective internal resistances of the cells and the respective heat removal abilities of the locations.

13. The battery of claim 12, wherein at least one of the elementary cells comprise lithium.

14. The battery of claim 12, wherein the plurality of elementary cells are series-connected.

15. The battery of claim 12 wherein the locations having the highest heat removal abilities are assigned to the cells dissipating the largest quantity of energy by Joule effect.

16. The battery of claim 15 wherein the assignment of the locations to the cells comprises the following step sequence:
classifying the locations by order of heat removal ability;
classifying the cells by order of quantity of heat dissipated by Joule effect at a reference temperature; and
assigning the locations having the highest heat removal abilities to the cells dissipating the largest quantity of energy at said reference temperature.

15. The battery of claim 16 wherein the assignment of the locations to the plurality of cells comprises an initial assignment of the locations to the cells, and then further comprises one or a plurality of iterations of the following step sequence:
a) calculating, for each cell, the quantity of energy dissipated by Joule effect by the cell in operation, taking into account the heat removal capacity of the location assigned to the cell during a previous sequence;
b) calculating a criterion characteristic of the relevance of the assignment of the locations to the cells; and
c) defining a new assignment of the locations to the cells.

16. A method of forming a battery comprising a plurality of cells, comprising the steps of:
defining locations for receiving the cells and the relative positionings of these locations in the battery;
measuring the internal resistance of each cell;
determining, for each location, a parameter representative of the heat removal ability of the location; and
assigning a location in the battery to each cell, taking into account respective internal resistances of the cells and the respective heat removal abilities of the locations, wherein the assignment of the locations to the cells comprises the following step sequence:
classifying the locations by order of heat removal ability;
classifying the cells by order of quantity of heat dissipated by Joule effect at a reference temperature; and
assigning the locations having the highest heat removal abilities to the cells dissipating the largest quantity of energy at said reference temperature,
and then further comprises one or a plurality of iterations of the following step sequence:
a) calculating, for each cell, the quantity of energy dissipated by Joule effect by the cell in operation, taking into account the heat removal capacity of the location assigned to the cell during a previous sequence;
b) calculating a criterion characteristic of the relevance of the assignment of the locations to the cells; and
c) defining a new assignment of the locations to the cells.

17. The method of claim 16, wherein the plurality of cells are identical except for manufacturing dispersion.

18. The method of claim 16, wherein a plurality of iterations of said sequence are implemented, and wherein, at the end of said iterations, the most favorable assignment relative to said criterion is retained.

19. The method of claim 18, wherein said criterion is the maximum temperature difference between the different cells of the battery in operation.

20. The method of claim 18, wherein said criterion is the total electric power consumption of the battery.
